(19) United States
(12) Patent Application Publication
(10) Pub. No.: US 2024/0332912 A1
(43) Pub. Date: Oct. 3, 2024

(54) LASER ASSEMBLY, LASER MODULE, AND XR GLASSES

(71) Applicant: TDK CORPORATION, Tokyo (JP)

(72) Inventors: Takashi HONDA, Tokyo (JP); Takashi AOYAGI, Tokyo (JP); Makoto FUKUDA, Tokyo (JP); Tsuyoshi KOMAKI, Tokyo (JP); Ryohei FUKUZAKI, Hong Kong (HK)

(73) Assignee: TDK CORPORATION, Tokyo (JP)

(21) Appl. No.: 18/521,217

(22) Filed: Nov. 28, 2023

(30) Foreign Application Priority Data
Apr. 3, 2023 (JP) 2023-060193

(51) Int. Cl. H01S 5/40; G02B 27/01; H01S 5/00

(52) U.S. Cl. CPC H01S 5/4075; G02B 27/0172; H01S 5/0064; H01S 5/4093; G02B 2027/0178

(57) ABSTRACT

A laser assembly includes a plurality of laser light sources, a plurality of laser light source bases having main surfaces on which the laser light sources are placed and arranged apart from each other, an optical waveguide layer having at least an optical waveguide configured to guide laser light output from the laser light sources, an optical waveguide substrate having a main surface on which the optical waveguide layer is provided, and a plurality of metal films (M) configured to bond the laser light source bases with the optical waveguide substrate. The plurality of metal films (M) correspond to the plurality of laser light source bases and are arranged apart from each other.

### BACKGROUND OF THE INVENTION

### Field of the Invention

The present disclosure relates to a laser assembly, a laser module, and XR glasses.

Priority is claimed on Japanese Patent Application No. 2023-060193, filed Apr. 3, 2023, the content of which is incorporated herein by reference.

### Description of Related Art

XR glasses such as augmented reality (AR) glasses and virtual reality (VR) glasses are expected to be small wearable devices. The key to widespread use of wearable devices such as AR glasses and VR glasses is to implement miniaturization so that each function fits within the size of ordinary eyeglasses.

### PATENT DOCUMENTS

[Patent Document 1] PCT International Publication No. WO2021/149450

### SUMMARY OF THE INVENTION

In Patent Document 1, a compact integrated optical device in which a base for holding a laser diode and a substrate having a surface on which an optical waveguide is provided are bonded together in a state in which a light-emitting position of the laser diode and an optical waveguide position are accurately aligned via a metallic layer is disclosed.

FIG. 17 is a schematic plan view for describing an integrated optical device disclosed in Patent Document 1. FIG. 18 is a schematic cross-sectional view of the integrated optical device shown in FIG. 17 along line A-A′. FIG. 19 is a perspective view for describing a feature of the integrated optical device disclosed in Patent Document 1. FIG. 19A is a schematic perspective view of the integrated optical device including nine laser diodes. FIG. 19B is a schematic perspective view of a substrate having a surface on which an optical waveguide is provided. FIG. 19C is a schematic perspective view of a base for holding three laser diodes among the nine laser diodes. Reference signs in the drawing correspond to reference signs of the constituent elements of a laser assembly and a laser module of the present embodiment, which will be described below, and the constituent elements required for description will be described here.

The integrated optical device shown in the drawings includes a plurality of laser diodes 30 (30-1, 30-2, and 30-3); a plurality of separate bases 20 (20-1, 20-2, and 20-3) having main surfaces 21-1, 21-2, and 21-3 on which the laser diodes 30 are placed and arranged apart from each other; an optical waveguide layer 50 having optical waveguides 51 configured to guide laser light output from the laser diodes 30 (30-1, 30-2, and 30-3); a substrate 40 having a surface on which the optical waveguide layer 50 is provided; and a metal film configured to bond the bases 20 (20-1, 20-2, and 20-3) with the substrate 40.

In the integrated optical device shown in the drawings, the metal film has a three-layer structure and includes metallic layers 74 (74-1, 74-2, and 74-3) arranged on bonding surfaces 22 (22-1, 22-2, and 22-3) of the plurality of separate bases 20, a metallic layer 172 continuously formed in a band shape on a bonding surface 42 of the substrate 40, and a metallic layer 173 continuously formed in a band shape on the metallic layer 172 so that the metallic layer 173 overlaps the metallic layer 172.

When a moving image or the like is generated using such an integrated optical device, an electrical signal applied to the laser diode is an alternating current (AC) signal. In the case where the operation signal is an AC, as the size is reduced, capacitive coupling occurs when the metal film for bonding the base 20 with the substrate 40 includes a metallic layer continuously formed in a band shape and there is concern that electrical crosstalk may occur.

The present disclosure has been made in view of the above-described circumstances and an objective of the present disclosure is to provide a laser assembly, a laser module, and XR glasses in which the occurrence of crosstalk between light-emitting elements is suppressed.

The present disclosure provides the following means to solve the above-described problems.

According to a first aspect of the present disclosure, there is provided a laser assembly including: a plurality of laser light sources; a plurality of laser light source bases having main surfaces on which the plurality of laser light sources are placed and arranged apart from each other; an optical waveguide layer having optical waveguides configured to guide laser light output from the plurality of laser light sources; an optical waveguide substrate having a main surface on which the optical waveguide layer is provided; and a plurality of metal films configured to bond the plurality of laser light source bases with the optical waveguide substrate, wherein the plurality of metal films correspond to the plurality of laser light source bases and are arranged apart from each other.

According to a second aspect of the present disclosure, in the laser assembly according to the first aspect, each of the plurality of metal films is arranged in a recess provided on the optical waveguide substrate.

According to a third aspect of the present disclosure, in the laser assembly according to the first aspect, each of the plurality of metal films is arranged on a substrate-side bonding part defined by a groove part formed on the bonding surface of the optical waveguide substrate.

According to a fourth aspect of the present disclosure, in the laser assembly according to any one of the first aspect to the third aspect, the metal film includes Sn and a metal that can be eutectic with Sn.

According to a fifth aspect of the present disclosure, in the laser assembly according to any one of the first aspect to the fourth aspect, an antireflection film is formed between the bonding surface of the optical waveguide substrate and the metal film.

According to a sixth aspect of the present disclosure, in the laser assembly according to any one of the first aspect to the fifth aspect, the optical waveguide layer is a planar lightwave circuit (PLC) made of a glass material.

According to a seventh aspect of the present disclosure, in the laser assembly according to any one of the first aspect to the fifth aspect, the optical waveguide layer is a PLC made of a lithium niobate film.

According to an eighth aspect of the present disclosure, there is provided a laser module having a package in which the laser assembly according to any one of the first aspect to the seventh aspect is housed.

According to a ninth aspect of the present disclosure, there are provided XR glasses including the laser module according to the eighth aspect.

According to a laser assembly of the present disclosure, it is possible to provide a laser assembly in which the occurrence of crosstalk between light-emitting elements is suppressed.

### BRIEF DESCRIPTION OF THE DRAWINGS

FIG. 1 is a schematic plan view of a part of a laser assembly according to the present embodiment.

FIG. 2 is a schematic cross-sectional view of the laser assembly shown in FIG. 1 along line A-A′.

FIG. 3A is a perspective view of a laser light source base on which three laser light sources are mounted.

FIG. 3B is a perspective view of an optical waveguide substrate having an optical waveguide.

FIG. 4 is a schematic cross-sectional view along line B-B′ in the laser assembly shown in FIG. 1.

FIG. 5A is a diagram schematically showing a structure in which both a first metal film 74 and a second metal film 72 are relatively retained.

FIG. 5B is a diagram schematically showing a structure in which the whole of the first metal film 74 and the second metal film 72 is alloyed to form a eutectic layer.

FIG. 6 is an SEM image of a cross section of a bonding part between the laser light source base and the optical waveguide substrate.

FIG. 7 is a schematic perspective view of the optical waveguide substrate seen from a bonding surface side and a schematic plan view showing a part thereof that is enlarged.

FIG. 8A is a schematic cross-sectional view and a schematic plan view showing one of two types of structures corresponding to the schematic plan view shown in FIG. 7.

FIG. 8B is a schematic cross-sectional view and a schematic plan view showing the other structure.

FIG. 9 is a schematic cross-sectional view corresponding to FIG. 2 for another example of a laser assembly.

FIG. 10 is a schematic plan view of a laser module according to the present embodiment.

FIG. 11 is a schematic cross-sectional view of the laser module shown in FIG. 10 along an X-Z plane.

FIG. 12 is a conceptual diagram of a laser assembly with an optical waveguide layer having an optical waveguide made of a lithium niobate film.

FIG. 13A is a schematic plan view obtained by enlarging a region surrounding a near-infrared laser light source and a corresponding optical waveguide.

FIG. 13B is a schematic cross-sectional view along line X1-X1 in FIG. 13A.

FIG. 14 is a schematic plan view of the laser assembly seen from an output surface of visible laser light and near-infrared laser light.

FIG. 15 is a conceptual diagram for describing XR glasses according to the present embodiment.

FIG. 16 is a conceptual diagram showing a state in which an image is directly projected onto a retina by laser light output from the laser module according to the embodiment.

FIG. 17 is a schematic plan view of a part of an integrated optical device.

FIG. 18 is a schematic cross-sectional view along line A-A′ in the integrated optical device shown in FIG. 1.

FIG. 19A is a schematic perspective view of the integrated optical device.

FIG. 19B is a perspective view of a subcarrier on which three laser light sources are mounted.

FIG. 19C is a perspective view of an optical waveguide substrate having an optical waveguide.

### DETAILED DESCRIPTION OF THE INVENTION

Hereinafter, embodiments will be described in detail with reference to the drawings as appropriate. In the drawings used in the following description, featured parts may be enlarged for convenience such that the features of the present disclosure are easier to understand, and dimensional ratios and the like of the respective components may be different from actual ones. Materials, dimensions, and the like exemplified in the following description are examples, the present disclosure is not limited thereto, and modifications can be appropriately made in a range in which advantageous effects of the present disclosure are exhibited.

### [Laser Assembly]

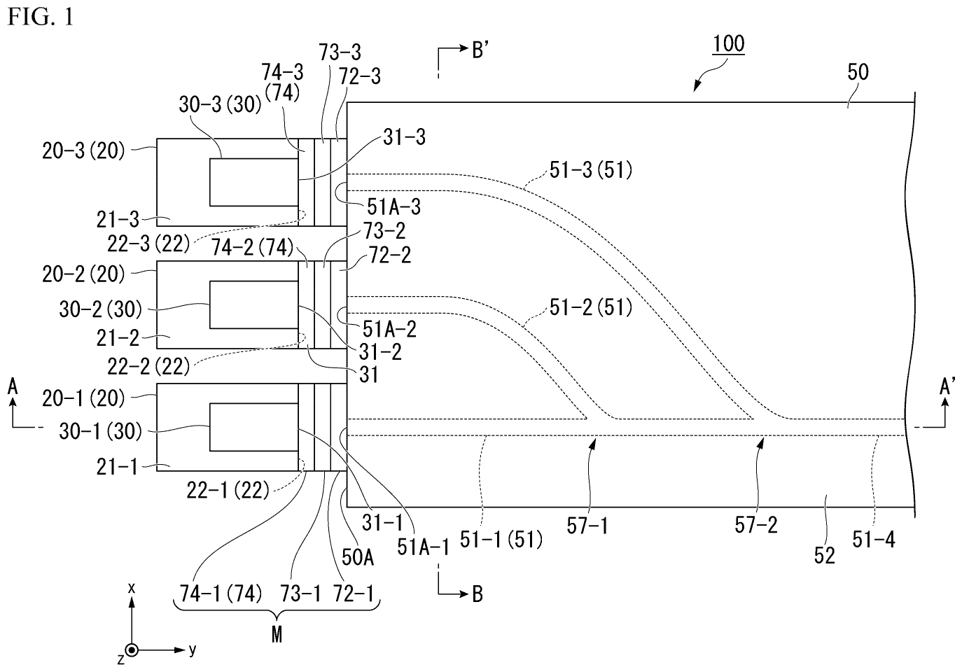

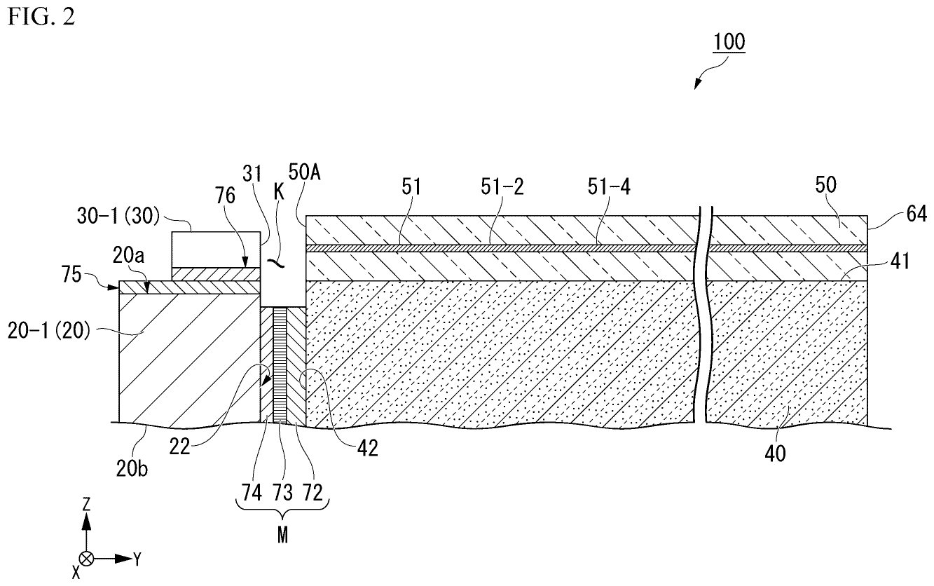

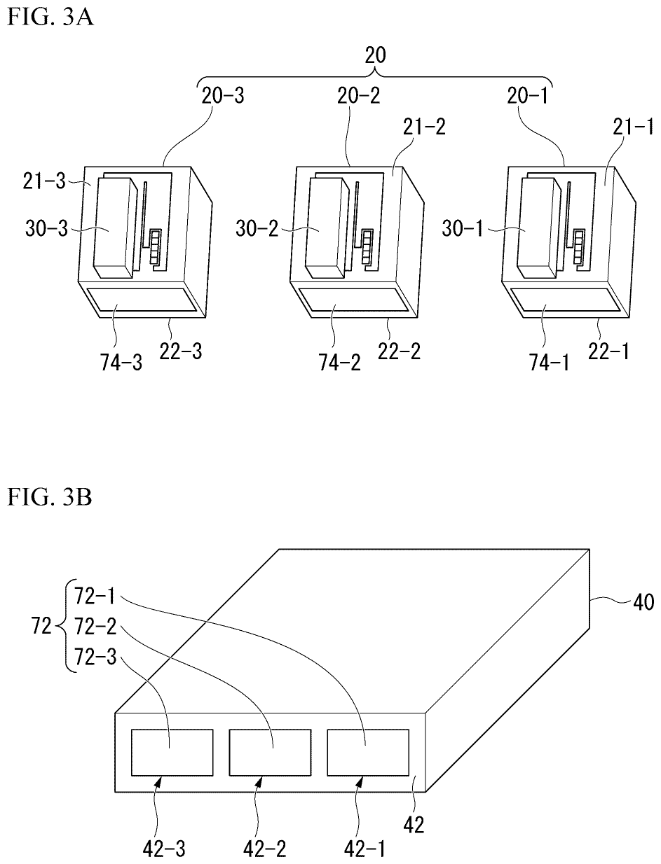

FIG. 1 is a schematic plan view of a part of a laser assembly of the present embodiment. FIG. 2 is a schematic cross-sectional view of the laser assembly shown in FIG. 1 along line A-A′. FIG. 3 is a perspective view for describing features of the present disclosure. FIG. 3A is a perspective view of a laser light source base on which three laser light sources are mounted and FIG. 3B is a perspective view of an optical waveguide substrate having an optical waveguide.

A laser assembly 100 shown in FIG. 1 includes three laser light sources 30 (30-1, 30-2, and 30-3); three laser light source bases 20 (20-1, 20-2, and 20-3) having main surfaces 21-1, 21-2, and 21-3 on which the three laser light sources 30 (30-1, 30-2, and 30-3) are placed and arranged apart from each other; an optical waveguide layer 50 having at least an optical waveguide 51 configured to guide laser light output from the three laser light sources 30 (30-1, 30-2, and 30-3); an optical waveguide substrate 40 having a main surface on which the optical waveguide layer 50 is provided; and metal films M configured to bond the laser light source bases 20 (20-1, 20-2, and 20-3) with the optical waveguide substrate 40. The metal films M (72, 73, and 74) are arranged between base-side bonding surfaces 22 (22-1, 22-2, and 22-3) of the laser light source bases 20 (20-1, 20-2, and 20-3) and a plurality of substrate-side bonding parts 42-1, 42-2, and 42-3 corresponding to the base-side bonding surfaces 22-1, 22-2, and 22-3 and arranged apart from each other on a bonding surface 42 of the optical waveguide substrate 40 and bond the laser light source bases 20-1, 20-2, and 20-3 with the optical waveguide substrate 40.

### <Laser Light Source and Laser Light Source Base>

Various types of laser elements can be used as the laser light source 30. For example, commercially available laser diodes (LDs) of red light, green light, blue light, near-infrared light, ultraviolet light, and the like can be used. Light with a peak wavelength of 300 nm or more and 830 nm or less can be used as red light, light with a peak wavelength of 500 nm or more and 600 nm or less can be used as green light, and light with a peak wavelength of 380 nm or more and 500 nm or less can be used as blue light. Also, light with a peak wavelength of 830 nm or more and 2000 nm or less can be used as near-infrared light.

In a laser assembly 100 shown in FIG. 1, the laser light sources 30-1, 30-2, and 30-3 are assumed to be an LD that emits red light, an LD that emits green light, and an LD that emits blue light, respectively. The LDs 30-1, 30-2, and 30-3, for example, can be mounted on separate laser light source bases (which may be referred to as subcarriers hereinafter) 20-1, 20-2, and 20-3, respectively, as bare chips (unpackaged chips).

The subcarriers 20-1, 20-2, and 20-3 are made of, for example, aluminum nitride (AlN), aluminum oxide (Al₂O₃), silicon (Si), or the like.

Metal films 75 and 76 are provided between the subcarrier 20 and the LD 30 (see FIG. 2). The subcarrier 20 and the LD 30 are connected via the metal films 75 and 76. A method of forming the metal films 75 and 76 is not particularly specified and a known method can be used, but a known method such as sputtering, vapor deposition, or application of a pasted metal can be used. The metal films 75 and 76 may include, for example, one or more metals selected from the group consisting of gold (Au), platinum (Pt), silver (Ag), lead (Pb), indium (In), nickel (Ni), titanium (Ti), tantalum (Ta), tungsten (W), an alloy of gold (Au) and tin (Sn), a tin (Sn)-silver (Ag)-copper (Cu)-based solder alloy (SAC), SnCu, InBi, SnPdAg, SnBiIn, and PbBiIn or may be composed of one or more metals selected from this group.

### <Optical Waveguide Layer and Optical Waveguide Substrate>

The optical waveguide layer 50 has at least an optical waveguide for guiding laser light output from a laser light source. This optical waveguide layer is not particularly limited, and for example, a known structure can be adopted. Examples of the optical waveguide layer are shown below.

The optical waveguide layer 50 is referred to as a planar lightwave circuit (PLC). Hereinafter, the optical waveguide layer 50 may be referred to as a PLC 50. Also, the optical waveguides 51-1, 51-2, and 51-3 may be referred to as cores 51-1, 51-2, and 51-3.

The optical waveguide layer 50 is formed on the optical waveguide substrate 40, and the laser light source 30 is mounted on the mounted subcarrier 20 as described above. The optical waveguide substrate 40 and the subcarrier 20 are metal-bonded and integrated.

This metal bonding enables accurate optical axis placement and implements miniaturization.

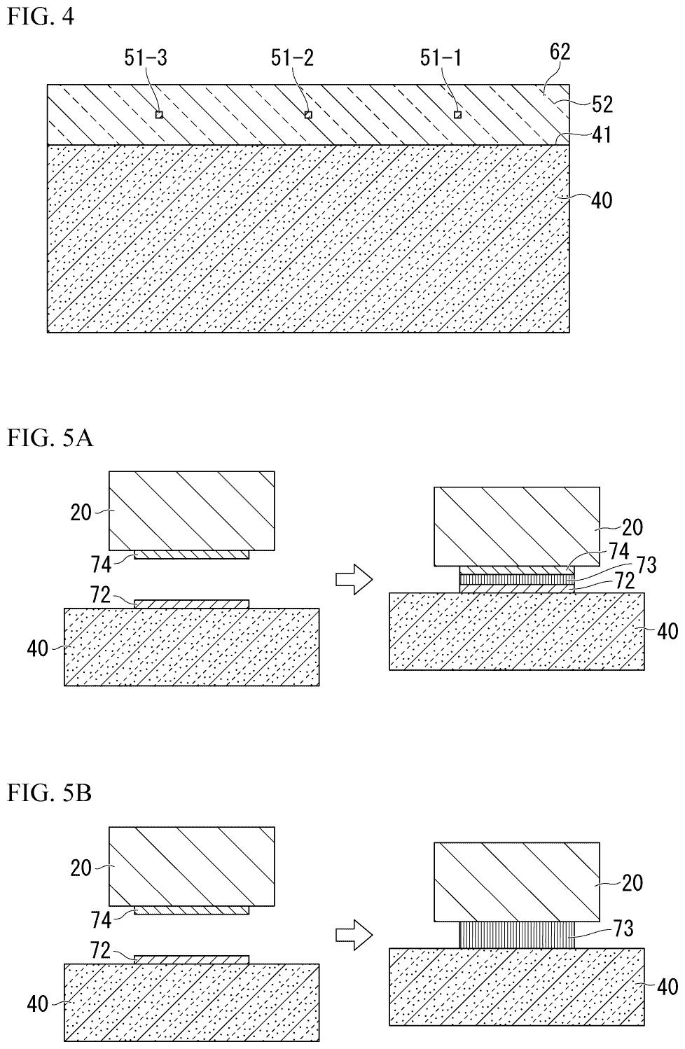

FIG. 4 shows a schematic cross-sectional view along line B-B′ of FIG. 1.

The optical waveguide substrate 40 is made of, for example, silicon (Si). The PLC 50 is fabricated integrally with the optical waveguide substrate 40 on the upper surface 41 in a known semiconductor process including photolithography or dry etching to be used when a fine structure such as an integrated circuit is formed. As shown in FIG. 1, cores 51-1, 51-2, and 51-3 equal in number to the LDs 30-1, 30-2, and 30-3 and a cladding 52 surrounding the cores 51-1, 51-2, and 51-3 are provided on the PLC 50. A thickness of the cladding 52 and widthwise dimensions of the cores 51-1, 51-2, and 51-3 are not particularly limited. For example, the cores 51-1, 51-2, and 51-3 each having a widthwise dimension of about several microns are arranged in the cladding 52 having a thickness of about 50 μm.

The cores 51-1, 51-2, and 51-3 and the cladding 52 are made of, for example, quartz. Hereinafter, it may be referred to as a quartz-based PLC 50. The refractive indices of the cores 51-1, 51-2, and 51-3 are greater than the refractive index of the cladding 52 by a prescribed value. Thereby, light input to each of the cores 51-1, 51-2, and 51-3 propagates through each core while being totally reflected at an interface between each core and the cladding 52. The cores 51-1, 51-2, and 51-3 are doped with impurities of germanium (Ge) and the like in an amount corresponding to the aforementioned prescribed value.

As shown in FIGS. 1 and 2, the cores 51-1, 51-2, and 51-3 are gathered together on the front side of the PLC 50 reaching the output surface 64. That is, the cores 51-1, 51-2, and 51-3 merge in order toward the front in the x-direction and merge into one core 51-4. Preferably, the cores 51-1, 51-2, and 51-3 are connected to the core 51-4 at a radius of curvature greater than or equal to a prescribed radius of curvature so that light leaking from the cores 51-1, 51-2, and 51-3 does not occur.

According to metal bonding between the optical waveguide substrate 40 and the subcarrier 20, each core and an LD corresponding thereto are arranged to face each other in a state in which the optical axis is precisely aligned so that centers of input ports of the cores 51-1, 51-2, and 51-3 of the PLC 50 substantially coincide with optical axes of output light from the LDs 30-1, 30-2, and 30-3 corresponding thereto.

As shown in FIG. 2, an input surface 50A of the PLC 50 is arranged to face the output surface 31 of the LD 30. Specifically, the output port 31-1 of the LD 30-1 faces an input port 51A-1 of the waveguide 51-1. The optical axis of the red light emitted from the LD 30-1 substantially overlaps the center of the input port 51A-1 in the x-direction and the z-direction. Similarly, the output port 31-2 of the LD 30-2 faces an input port 51A-2 of the waveguide 51-2. The optical axis of the green light emitted from the LD 30-2 substantially overlaps the center of the input port 51A-2 in the x-direction and the z-direction. The output port 31-3 of the LD 30-3 faces an input port 51A-3 of the waveguide 51-3. The optical axis of the blue light emitted from the LD 30-3 substantially overlaps the center of the input port 51A-3 in the x-direction and the z-direction. With such a configuration and arrangement, at least some of the red light, green light, and blue light emitted from the LDs 30-1, 30-2, and 30-3 can be input to the waveguides 51-1, 51-2, and 51-3.

As shown in FIG. 1, red light, green light, and blue light emitted from the LDs 30-1, 30-2, and 30-3 are input to the cores 51-1, 51-2, and 51-3, and then propagate through the cores. The red light and the green light propagating through the cores 51-3 and 51-2 are coupled at a prescribed merging position 57-1 behind the merging position 57-2 in the y-direction. The coupled red and green light and the blue light propagating through the core 51-2 are combined at the merging position 57-2. The RGB light combined at the merging position 57-2 propagates through the core 51-4, reaches the output surface 64, and is output from the output surface 64.

### <Bonding Part>

The three separate laser light source bases 20-1, 20-2, and 20-3 and the optical waveguide substrate 40 are bonded via the metal films M interposed therebetween.

The metal films M are arranged between the base-side bonding surfaces 22-1, 22-2, and 22-3 of the three separate laser light source bases 20-1, 20-2, and 20-3 and three substrate-side bonding parts 42-1, 42-2, and 42-3 arranged apart from each other on the bonding surface 42 of the optical waveguide substrate 40 corresponding to the base-side bonding surfaces 22-1, 22-2, and 22-3.

The metal films M are arranged only on the substrate-side bonding parts 42-1, 42-2, and 42-3 which are arranged apart from each other and are separate films instead of continuously formed films, so that the occurrence of capacitive coupling is suppressed and crosstalk is prevented.

For convenience, the metal film M shown in FIGS. 1 and 2 is drawn in a three-layer structure in consideration of the manufacturing process of the metal film M (or a bonding process between the laser light source base and the optical waveguide substrate). Also, when the metal film M is described, each of the three layers may be described.

That is, for convenience, the metal film M shown in the drawing is drawn to have a three-layer structure including first metal films 74 (74-1, 74-2, and 74-3) arranged on the base-side bonding surfaces 22-1, 22-2, and 22-3 of the separate laser light source bases 20-1, 20-2, and 20-3, second metal films 72 (72-1, 72-2, and 72-3) corresponding to the base-side bonding surfaces 22-1, 22-2, and 22-3 and arranged on the three substrate-side bonding parts 42-1, 42-2, and 42-3 arranged apart from each other on the bonding surface 42 of the optical waveguide substrate 40, and a eutectic layer 73 arranged between the first metal film 74 and the second metal film 72.

In actual bonding, when the first metal film and the second metal film are sufficiently thin, an alloy layer (eutectic layer) is formed and the first metal film and the second metal film do not remain. On the other hand, if one of the first metal film and the second metal film is thick, only the surface side of the thick metal film is eutectic, a part of the laser light source base side or the optical waveguide substrate side becomes eutectic, and the other metal film may be entirely eutectic, but clear layer identification (interface identification) becomes difficult.

As described above, in actual bonding, the film structure of the metal film M varies depending on the conditions of the manufacturing process of the metal film M, and characteristic aspects of the film structure are conceptually drawn in the drawings.

For example, a structure in which one or both of the first metal film 74 and the second metal film 72 is relatively retained or a structure in which the whole of the first metal film 74 and the second metal film 72 is alloyed to form a eutectic layer can be adopted. FIG. 5A is a diagram schematically showing a structure in which both the first metal film 74 and the second metal film 72 are relatively retained in the former structure and FIG. 5B is a diagram schematically showing a structure in which the whole of the first metal film 74 and the second metal film 72 is alloyed to form a eutectic layer.

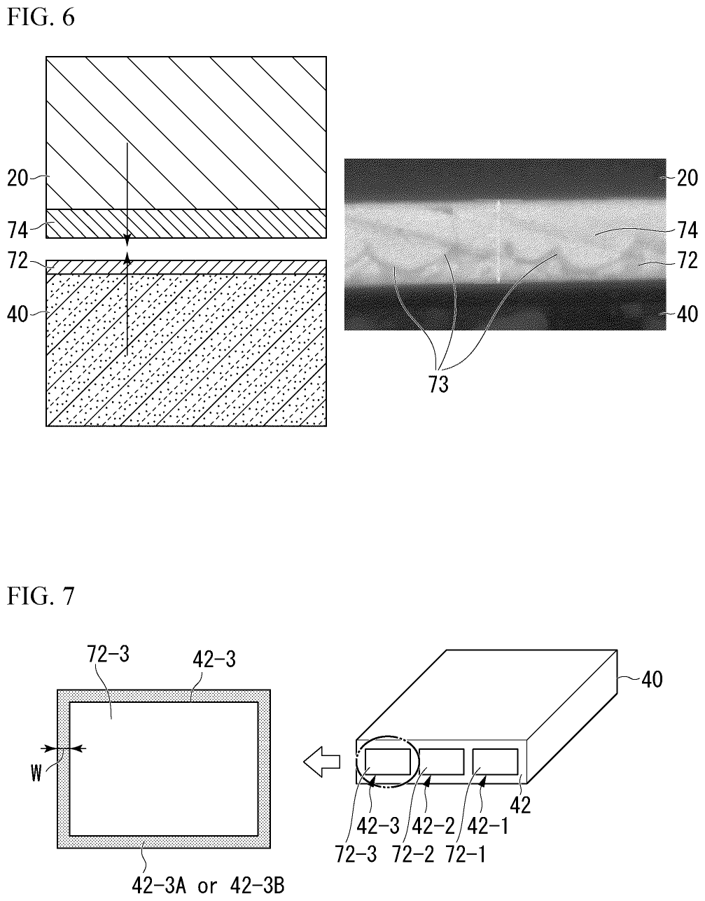

FIG. 6 is a schematic diagram of a cross section of a bonding part obtained by performing alignment so that the first metal film 74 and the second metal film 72 overlap after an Au layer is formed as the first metal film 74 and a SAC layer is formed as the second metal film 72, melting the Au layer 74 and the SAC layer 72 by applying laser light to the subcarrier 20, and forming a eutectic layer between the Au layer 74 and the SAC layer 72 and a scanning electron microscope (SEM) image.

From the SEM image, it can be seen that SAC is eutectic and diffused inside of the Au layer.

The second metal film 72 arranged on the substrate-side bonding parts 42-1, 42-2, and 42-3 is preferably made of Sn or an alloy containing Sn such as Sn—Ag—Cu.

Also, the first metal films 74 arranged on the base-side bonding surfaces 22-1, 22-2, and 22-3 are preferably made of a metal that can be eutectic with Sn, for example, one selected from the group consisting of Au, Si, Al, Ni, Pb, Zn, and Pt, or an alloy thereof, but Au or an alloy containing Au is more preferable.

The three-layer structure of the metal film M shown in FIG. 5 may be reversed. That is, a structure in which the second metal film 72 is arranged on the laser light source base 20 side and the first metal film 74 is provided on the optical waveguide substrate 40 side may be adopted.

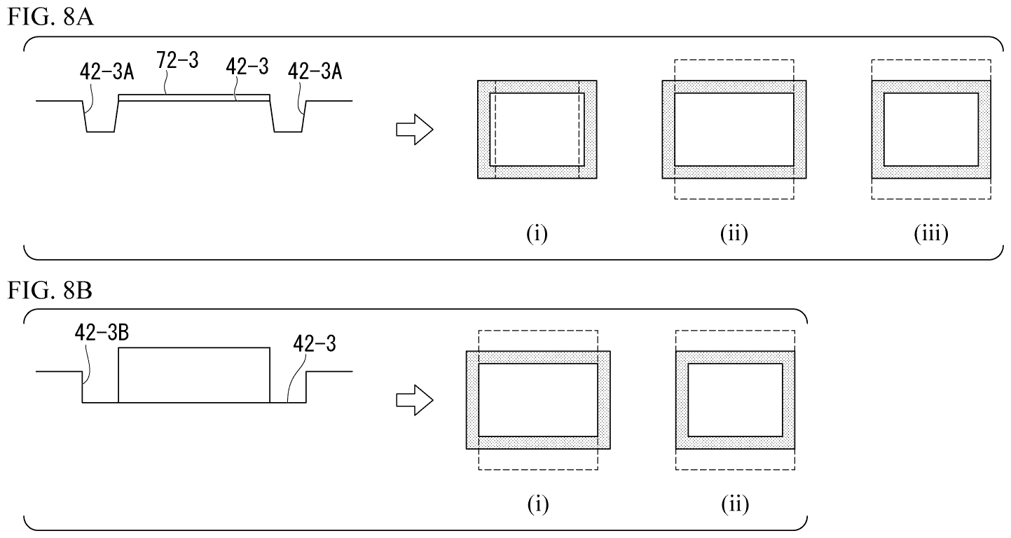

FIG. 7 is a schematic perspective view of the optical waveguide substrate 40 seen from the bonding surface 42 side and a schematic plan view obtained by enlarging a part thereof. FIGS. 8A and 8B are schematic cross-sectional views and schematic plan views showing two types of structures corresponding to the schematic plan view shown in FIG. 7.

The two types of structures shown in FIGS. 7 and 8 are structures for ensuring the separation of the second metal films 72-1, 72-2, and 72-3 arranged on the substrate-side bonding part on the optical waveguide substrate 40 side.

The structure shown in FIG. 8A has a groove part 42-3A to surround a substrate-side bonding part around the substrate-side bonding parts 42-1, 42-2, and 42-3 arranged apart from each other in correspondence with the base-side bonding surfaces 22-1, 22-2, and 22-3 of the separate laser light source bases 20-1, 20-2, and 20-3 (only a groove part around the substrate-side bonding parts 42-3 is shown in the drawing). The second metal film 72 is formed to be arranged inside of the groove part.

By providing the groove part 42-3A, the separation of the second metal films 72-1, 72-2, and 72-3 can also be reliably ensured during bonding.

The three schematic plan views (i) to (iii) shown on the right side of the schematic cross-sectional view of FIG. 8A indicate relationships between sizes of the substrate-side bonding part and the groove part and the base-side bonding surface (a dotted-line frame in the drawing).

The structure shown in FIG. 8B has recessed parts 43-3B for forming the second metal films 72-1, 72-2, and 72-3 for the substrate-side bonding parts 42-1, 42-2, and 42-3 arranged apart from each other (only a recess around the substrate-side bonding part 42-3 is shown in the drawing). In this structure, a substrate-side bonding part is provided on a bottom surface of the recessed part and the second metal film 72 is formed to be arranged on the substrate-side bonding part in the recessed part.

By providing the recessed part 43-3B, the separation of the second metal films 72-1, 72-2, and 72-3 can also be reliably ensured during bonding.

The two schematic plan views (i) and (ii) shown on the right side of the schematic cross-sectional view of FIG. 8B show relationships between sizes of the substrate-side bonding part and the groove part and the base-side bonding surface (a dotted-line frame in the drawing).

A groove or a recess for the first metal film 74 may also be provided on the bonding surface of the laser light source base.

The groove part or the recessed part can be formed in known semiconductor processes including photolithography and dry etching.

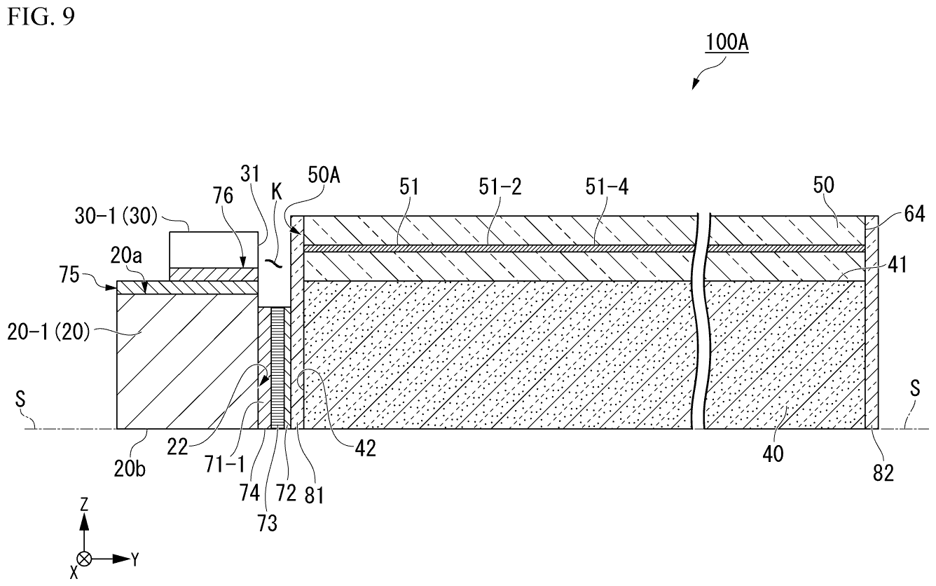

An antireflection film 81 is provided between the LD 30 and the PLC 50 in a laser assembly 100A shown in FIG. 9. For example, the antireflection film 81 is integrally formed on the side surface 42 of the substrate 40 and the input surface 50A of the PLC 50. However, the antireflection film 81 may be formed only on the input surface 50A of the PLC 50.

In the laser assembly 100A shown in FIG. 9, an antireflection film 82 is provided not only on the input surface 50A but also on the output surface 64.

The antireflection films 81 and 82 are films for preventing input light or output light for the PLC 50 from being reflected in a direction opposite a direction in which the input light or the output light enters each surface from the input surface 50A or the output surface 64 and increasing the transmittance of the input light or the output light. The antireflection films 81 and 82 are multilayer films, each of which is formed of, for example, a plurality of types of dielectrics alternately laminated at a prescribed thickness corresponding to the wavelengths of red light, green light, and blue light that are input light. Examples of the above-described dielectric include titanium oxide (TiO₂), tantalum oxide (Ta₂O₅), silicon oxide (SiO₂), aluminum oxide (Al₂O₃), and the like.

An output surface 31 of the LD 30 and an input surface 50A of the PLC 50 are arranged at a prescribed interval. The input surface 50A faces the output surface 31 and there is a gap K between the output surface 31 and the input surface 50A in the x-direction. Considering the fact that the laser assembly 100A is used for XR glasses, a light intensity required for the XR glasses, and the like, a size of the gap (spacing) K in the x-direction is, for example, greater than 0 μm and less than or equal to 5 μm.

Although the laser assembly 100A shown in FIG. 9 will be described below, the same can also be similarly applied to the laser assembly 100.

The laser assembly 100A is provided so that a bottom surface (base bottom surface) 20b facing a top surface (surface) 20a of a subcarrier (laser light source base) 20 (20-1, 20-2, and 20-3) and a bottom surface (substrate bottom surface) 43 facing the top surface (surface) 41 of the substrate 40 are positioned on substantially the same plane S as each other. In the laser assembly 100A, because the subcarrier 20 and the substrate 40 are connected via a metal film, the occurrence of position misalignment due to a heating process is remarkably suppressed compared to the case where the connection is made with an adhesive.

Also, the term “substantially the same plane S” mentioned here allows slight misalignment between a bottom surface (base bottom surface) 20b and the bottom surface (substrate bottom surface) 43. Specifically, although the misalignment of a range of 20 μm or less is allowed for the thickness of the substrate 40 along the z-direction, it is preferable that the misalignment be small, the misalignment of a range of 10 μm or less is more preferred, and the misalignment of a range of 5 μm or less is more preferred.

As in the illustrated laser assembly 100A, if the bottom surface 20b of the subcarrier 20 and the bottom surface 43 of the substrate 40 are formed on substantially the same plane S, both the subcarrier 20 and the substrate 40 can be bonded, for example, on a single plane of a package or heatsink. Thereby, compared to the case where the bottom surface of the subcarrier and the bottom surface of the substrate are not substantially coplanar and only one of the bottom surfaces can be bonded, the laser assembly 100A can efficiently radiate heat generated in the operation of the LD (optical semiconductor element) 30 from both the bottom surface 20b of the subcarrier 20 and the bottom surface 43 of the substrate 40.

Also, as in the illustrated laser assembly 100A, by providing the bottom surface 20b of the subcarrier 20 and the bottom surface 43 of the optical waveguide substrate 40 on substantially the same plane S, when the optical module is bonded to another substrate or the like on the single plane, because the substrate and the like can be bonded on the single plane on both sides of the bottom surface 20b of the subcarrier 20 and the bottom surface 43 of the optical waveguide substrate 40, the laser assembly 100A with high bonding strength and excellent impact resistance can be implemented.

For example, when the bottom surface of the subcarrier is located in the +z-direction as compared with the bottom surface of the substrate, i.e., when the bottom surface of the subcarrier is spaced more upward from a base 180 of the package 110 (see FIG. 11) than the bottom surface of the substrate, the size of the first side surface of the subcarrier is small and the heat dissipation cannot be efficiently performed. When the bonding strength with the substrate is not sufficient and wire bonding to be described below is performed, there is a case where the subcarrier slips. However, the illustrated laser assembly 100A can improve heat dissipation and impact resistance because a sufficient size of the side surface 22 can be ensured, heat can be radiated from the bottom surface 20b and the side surface 22, and bonding with the optical waveguide substrate 40 can be sufficiently performed. By improving impact resistance, for example, the LD 30 is maintained at an optimum position with respect to the PLC 50. Therefore, the laser assembly 100A can exhibit desired light utilization efficiency and optical characteristics, and the reliability of the laser assembly 100A can be improved.

### [Laser Module]

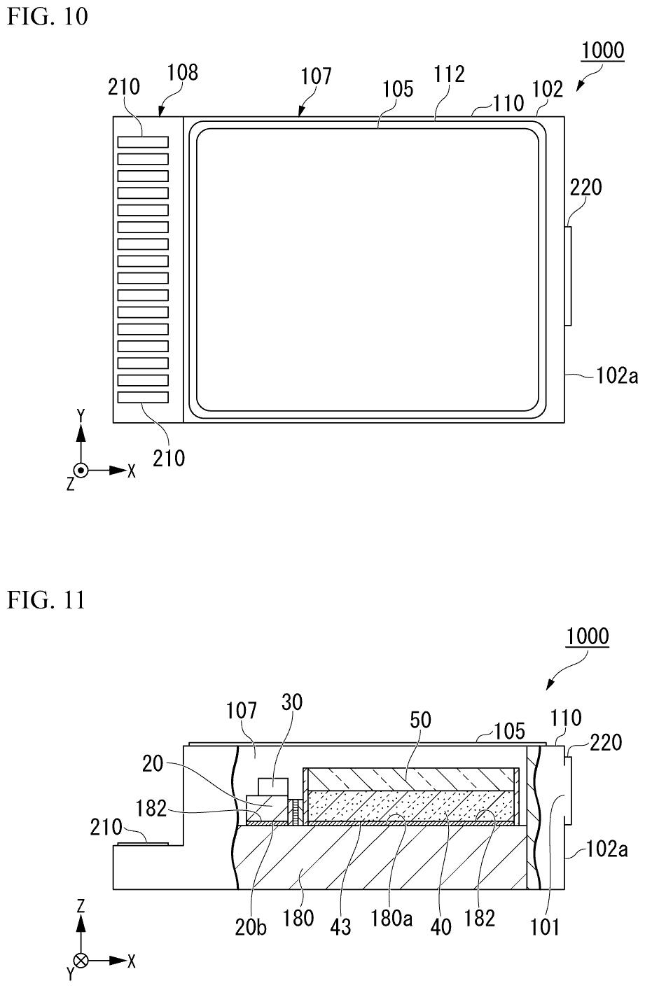

FIG. 10 is a schematic plan view of a laser module of the present embodiment. FIG. 11 is a schematic cross-sectional view of the laser module shown in FIG. 10 along an X-Z plane.

In a laser module 1000 shown in FIG. 10, a laser assembly according to the above-described embodiment is housed in a package 110.

Known components other than the laser assembly according to the above-described embodiment may be provided inside of the package 110. For example, a light receiver (photodetector (PD)) can be housed.

If the PD is provided, it is possible to check optical output fluctuations in the LD by observing a current flowing through the PD. Also, by monitoring the current flowing through the PD, a drive current of the LD can be controlled so that the output becomes constant.

The package 110 includes a body 102 having a cavity structure and a cover 105 covering the body 102.

The body 102 has a bottom on which members housed therein are placed and a wall part (sidewall part) 102a arranged to surround the members from the side.

A light transmission window 101 through which the laser light L output from the laser light source 30 can be optically transmitted is formed in the wall part (sidewall part) 102a arranged in a direction in which the laser light is output.

The light transmission window (opening) 101 is formed in the sidewall part 102a near an output part of the laser light L output from the laser module 1000 in the sidewall part of the housing portion 107. The opening 101 is formed to be substantially centered on a position intersecting the optical axis of the laser light output from the sidewall part 102a. The opening 101 is tightly covered with the glass plate 220 from the outside of the sidewall part 102a. That is, the housing portion 107 is hermetically sealed by the glass plate 220 in addition to the cover 105. Although the glass plate 220 is used for airtight sealing, the present disclosure is not limited to the glass plate as long as it is a material through which laser light can pass. An antireflection film (not shown) may be provided on both surfaces of the glass plate 220.

An electrode portion 108 is arranged on the front side of the housing portion 107 in the x-direction, i.e., on the rear side in the x-direction. The upper surface of the electrode portion 108 is positioned below the upper surface of the housing portion 107. The bottom surface of the electrode portion 108 is positioned at substantially the same height as the bottom surface of the housing portion 107. A plurality of external electrode pads 210 are provided on the upper surface of the electrode portion 108 at intervals in the y-direction.

As shown in FIG. 9, the base 180 for installing the optical module including the LD 30, the subcarrier 20 on which the LD 30 is mounted, the PLC 50, and the optical waveguide substrate 40 on which the PLC 50 is formed is provided at a prescribed position on the bottom of the housing portion 107. This optical module is mounted on the base 180. In other words, this optical module is arranged in an internal space of the housing portion 107. Because this optical module is formed so that the bottom surface (base bottom surface) 20b of the subcarrier (laser light source base) 20 and the bottom surface (substrate bottom surface) 43 of the optical waveguide substrate 40 are positioned substantially on the same plane S, the subcarrier 20 and the optical waveguide substrate 40 in this optical module are both bonded to an upper surface 180a (one inner surface) of the base 180.

It is only necessary to bond the bottom surface (base bottom surface) 20b of the subcarrier 20 and the bottom surface (substrate bottom surface) 43 of the optical waveguide substrate 40 to the upper surface 180a (one inner surface) of the base 180 via an adhesive layer 182. The adhesive layer 182 is made of a resin material mixed with a filler to improve thermal conductivity. Examples of the resin constituting the adhesive layer 182 include epoxy resin. Also, copper powder, aluminum powder, alumina powder, or the like can be used as a filler for improving the thermal conductivity of the resin.

Also, in order to maintain thermal conductivity of a certain level or higher, the adhesive layer 182 preferably has a thermal conductivity of 0.5 W/m·K or more, preferably has a thermal conductivity of 1 W/m·K or more, and more preferably has a thermal conductivity of 4 W/m·K or more.

Thus, by bonding both the subcarrier 20 of the optical module and the optical waveguide substrate 40 with the upper surface 180a of the base 180 of the package 110, the heat generated according to the operation of the LD 30 can be efficiently radiated from both the bottom (base bottom surface) 20b of the subcarrier 20 and the bottom surface (substrate bottom surface) 43 of the optical waveguide substrate 40 to the base 180. Furthermore, by bonding both the bottom surface 20b of the subcarrier 20 and the bottom surface 43 of the optical waveguide substrate 40 using an adhesive layer made of a resin mixed with a filler, heat can be efficiently propagated from both the bottom surface 20b of the subcarrier 20 and the bottom surface 43 of the optical waveguide substrate 40 to the base 180.

Next, a case where an optical waveguide layer provided in a laser assembly in which the laser module is housed in a package is made of a lithium niobate film (LiNbO₃) will be described. The optical waveguide layer in this case may be hereinafter referred to as an LN-based PLC.

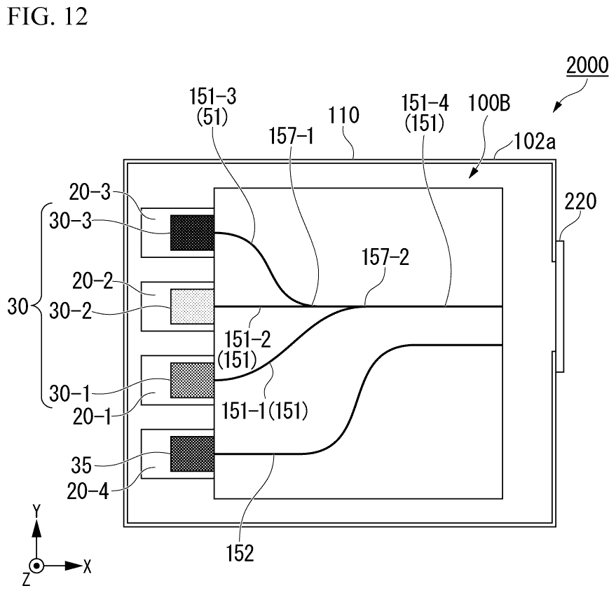

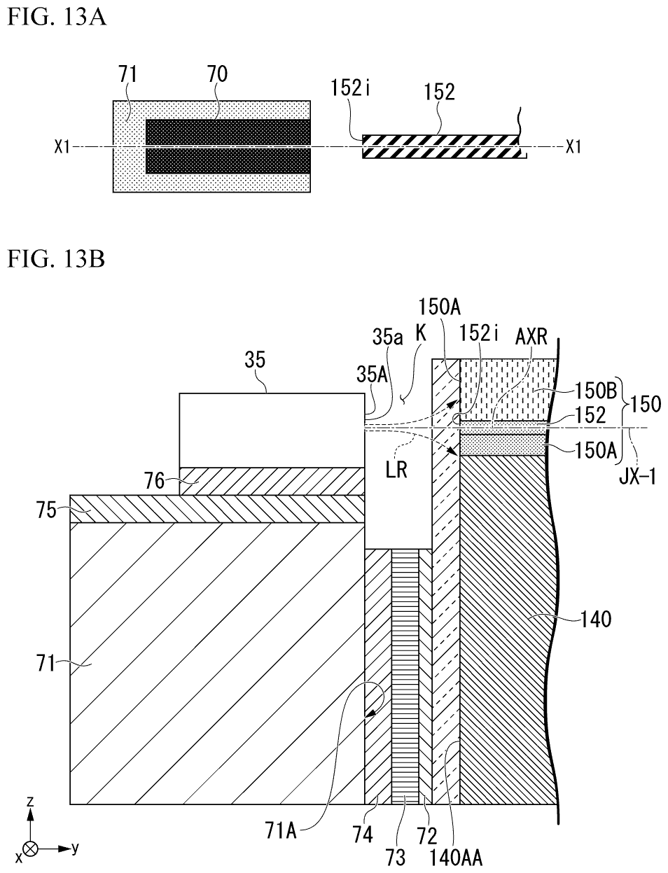

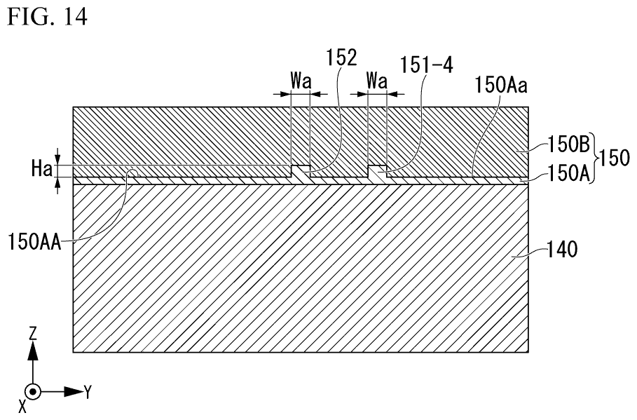

In FIG. 12, a conceptual diagram of a laser module including an optical waveguide layer having an optical waveguide made of a lithium niobate film is shown. FIG. 13A is a schematic plan view obtained by enlarging a region surrounding the near-infrared laser light source and an optical waveguide corresponding thereto, and FIG. 13B is a schematic cross-sectional view along line X1-X1 in FIG. 13A. FIG. 14 is a schematic plan view of the laser module viewed from the output surface of visible laser light and near-infrared laser light.

Members identical to those of the laser assembly and the laser module described above are denoted by the same reference signs, and description thereof may be omitted. In FIG. 12, an example in which the laser assembly has a near-infrared laser light source as a laser light source in addition to the RGB laser light sources is shown. Because near-infrared lasers are invisible, they can be used for eye tracking.

In a laser assembly 2000 shown in FIG. 12, a laser assembly 100B including the RGB laser light source 30, the laser light source base 20 on which the RGB laser light source 30 is placed, the near-infrared laser light source 35, and a laser light source base 20-4 on which the near-infrared laser light source 35 is placed, an optical waveguide substrate 140 having a main surface on which an LN-based PLC 150 is formed, and the metal films 72, 73, and 74 for bonding the laser light source base 20 and the laser light source base 20-4 and the optical waveguide substrate 140 is housed in the package 110.

The near-infrared laser light source 35 is mounted on the subcarrier 20-4 like the laser light source 30 and the LN-based PLC 150 is formed on the optical waveguide substrate 140.

The laser assembly 2000 includes the LN-based PLC 150 including optical waveguides 151 (151-1, 151-2, and 151-3) for guiding the laser light output from the laser light source 30 and an optical waveguide 152 for guiding the near-infrared laser light output from the near-infrared laser light source 35 within the package 110.

Also, in the laser assembly 2000, the optical waveguide substrate 140 on which the LN-based PLC 150 is formed, the subcarrier 20 on which the laser light source 30 is placed, and the subcarrier 20-4 on which the near-infrared laser light source 35 is placed are metal-bonded and integrated.

This metal bonding enables an accurate optical axis arrangement and miniaturization is implemented.

Examples of the optical waveguide substrate 140 include a sapphire substrate, a Si substrate, a thermal silicon oxide substrate, and the like.

Although there is no particular limitation as long as the film has a lower refractive index than the lithium niobate film when the optical waveguide 151 and the optical waveguide 152 are formed of a lithium niobate (LiNbO₃) film, a sapphire single-crystal substrate or a silicon single-crystal substrate is preferred as a substrate on which a single-crystal lithium niobate film can be formed as an epitaxial film. Although the crystal orientation of the single-crystal substrate is not particularly limited, for example, because the c-axis-oriented lithium niobate film has 3-fold symmetry, it is preferable that the underlying single-crystal substrate also have the same symmetry and the substrate of the c-plane in the case of a sapphire single-crystal substrate or the (111) plane in the case of a silicon single-crystal substrate is preferred.

In the laser assembly 2000, the optical waveguide layer (LN-based PLC) 150 includes a waveguide core film 150A having an optical waveguide 151 and an optical waveguide 152 and a waveguide cladding film 150B formed on the waveguide core film 150A to cover the optical waveguide 151 and the optical waveguide 152. The waveguide cladding film 150B has a smaller refractive index than the waveguide core film 150A. The waveguide cladding film 150B is made of, for example, SiInO, SiO₂, Al₂O₃, MgF₂, La₂O₃, ZnO, HfO₂, MgO, Y₂O₃, CaF₂, In₂O₃, or the like, or a mixture thereof.

Hereinafter, the waveguide core film 150A may be referred to as a lithium niobate film 150A.

The lithium niobate film is, for example, a c-axis-oriented lithium niobate film. The lithium niobate film is, for example, an epitaxial film having epitaxial growth on the optical waveguide substrate 140. The epitaxial film is a single-crystal film in which the crystal orientation is aligned by the base substrate. The epitaxial film is a film having a single-crystal orientation in the z-direction and the xy-plane direction and the crystals are aligned and oriented along the x-axis, the y-axis, and the z-axis. It is possible to prove whether or not the film formed on the optical waveguide substrate 140 is an epitaxial film, for example, by confirming the peak intensity and the pole at the orientation position in 2θ-θ X-ray diffraction.

The composition of lithium niobate is LiₓNbA_{y}O_{z}. A is an element other than Li, Nb, and O. x is 0.5 or more and 1.2 or less, preferably 0.9 or more and 1.05 or less. y is 0 or more and 0.5 or less. z is 1.5 or more and 4.0 or less, preferably 2.5 or more and 3.5 or less. The element A is, for example, K, Na, Rb, Cs, Be, Mg, Ca, Sr, Ba, Ti, Zr, Hf, V, Cr, Mo, W, Fe, Co, Ni, Zn, Sc, or Ce, and two or more of these elements may be combined.

A thickness of the lithium niobate film is, for example, 2 μm or less. A thickness of the lithium niobate film is a thickness of a portion other than a ridge portion. If the thickness of the lithium niobate film is thick, the crystallinity may deteriorate.

A thickness of the lithium niobate film is, for example, about 1/10 or more of the wavelength of the light that is used. If the thickness of the lithium niobate film is thin, light confinement becomes weak and light leaks to the optical waveguide substrate 140 and the waveguide cladding film 150B.

The optical waveguides 151 and 152 are pathways of light in which light propagates. The optical waveguides 151 and 152 are ridges protruding from a first surface 150AA of a slab layer 150Aa of the lithium niobate film 150A. Hereinafter, the optical waveguides 151-1, 151-2, 151-3, and 152 may be referred to as ridges 151-1, 151-2, 151-3, and 152, respectively. The first surface 150AA is an upper surface of a portion (slab layer 150Aa) other than the ridge portion of the lithium niobate film 150A. The lithium niobate film 150A includes the ridges 151-1, 151-2, 151-3, and 152 and the slab layer 150Aa.

A cross-sectional shape of the cross-sectional shape formation part of the ridge 151-4 and the ridge 152 shown in FIG. 14 is rectangular, but may be any shape as long as light can be guided. For example, it may be trapezoidal shape, triangular shape, semicircular shape, or the like. A width Wa of the ridge in the y-direction is preferably 0.3 μm or more and 5.0 μm or less, and the height of the ridge (a protruding height Ha from the first surface 150A) is preferably, for example, 0.1 μm or more and 1.0 μm or less.

As shown in FIG. 12, the optical waveguides 151-1, 151-2, and 151-3 are gathered together on the front side of the PLC 150 reaching the output surface. That is, the optical waveguides 151-1, 151-2, and 151-3 merge in order toward the front in the x-direction and merge into one optical waveguide 151-4. It is preferable to connect the optical waveguide 151-4 to the optical waveguides 151-1, 151-2, and 151-3 each having a radius of curvature greater than or equal to a prescribed radius of curvature so that light leaking from the optical waveguides 151-1, 151-2, and 151-3 does not occur.

According to metal bonding between the optical waveguide substrate 140 and the subcarriers 20 and 71, each ridge and an LD corresponding thereto are arranged to face each other in a state in which optical axis alignment is accurately made so that the center of the input port of each of the ridges 151-1, 151-2, 151-3, and 152 of the LN-based PLC 50 substantially coincides with an optical axis of the output light from the LD 30-1, 30-2, 30-3, and 35 corresponding thereto.

Input ports 151-1i, 151-2i, 151-3i, and 152i of the optical waveguides 151-1, 151-2, 151-3, and 152 face output ports of LDs 30-1, 30-2, 30-3, and 35 and are positioned so that light output from the output ports of the LDs 30-1, 30-2, 30-3, and 35 can be input to the input ports 151-1i, 151-2i, 151-3i, and 152i, such that the LDs 30-1, 30-2, 30-3, and 35 and the optical waveguides 151-1, 151-2, 151-3, and 152 are optically connected.

For example, an axis JX-1 of the input path substantially overlaps an optical axis AXR of the laser light LR output from an output port 35a of the LD 35. With such a configuration and arrangement, red light, green light, blue light, and near-infrared light emitted from the LDs 30-1, 30-2, 30-3, and 35 can be input to the input paths of the optical waveguides 151-1, 151-2, 151-3, and 152.

As shown in FIG. 12, red light, green light, and blue light emitted from the LDs 30-1, 30-2, and 30-3 are input to the ridges 151-1, 151-2, and 151-3, respectively, and then propagate in the ridges. The red light and green light propagating in the ridges 151-3 and 151-2 are coupled at a prescribed merging position 157-1 behind the merging position 157-2 in the x-direction. The red light and green light that are coupled and the blue light propagating in the ridge 151-2 are coupled at a merging position 57-2. The RGB light coupled at the merging position 57-2 propagates in the ridge 151-4, reaches the output surface, and is output from the output surface.

Also, near-infrared light emitted from the LD 35 propagates in the ridge 152, reaches the output surface, and is output from the output surface.

A side surface (first side surface) 71A of the subcarrier 71 facing the optical waveguide substrate 140 and a side surface (second side surface) 10AA of the optical waveguide substrate 140 facing the subcarrier 71 are connected via metal films (the first metal film 74, the second metal film 72, and the third metal film 73).

Each of the optical waveguides 151-1, 151-2, 151-3, and 152 provided in the LN-based PLC 150 may be a Mach-Zehnder type optical waveguide.

### [Xr Glasses]

In XR glasses according to the present embodiment, the laser module according to the above-described embodiment is mounted on the glasses.

The XR glasses (eyeglasses) are eyeglasses-type terminals and XR is a general term for virtual reality (VR), augmented reality (AR), and mixed reality.

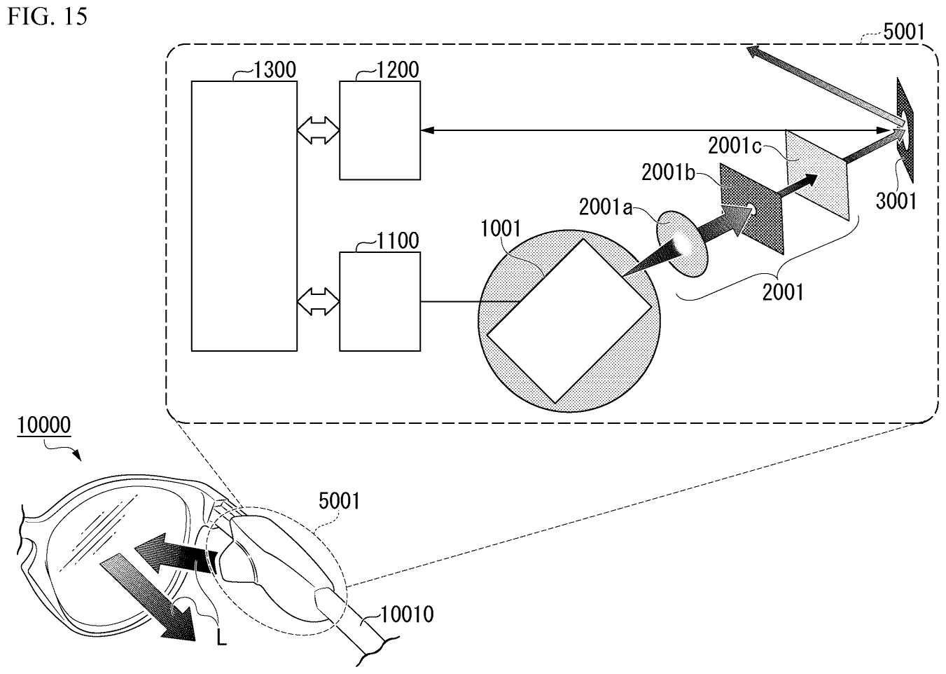

In FIG. 15, a conceptual diagram for describing the XR glasses according to the present embodiment is shown.

XR glasses 10000 shown in FIG. 15 have a laser module 1001 mounted on a frame 10010. Reference sign L denotes image display light.

In FIG. 15, an optical engine 5001 is a combination of the laser module 1001, an optical scanning mirror 3001, and an optics system 2001 connecting the laser module 1001 and the optical scanning mirror 3001 in the present specification. As the laser module 1001, any laser module according to the above-described embodiment is used.

For example, RGB laser light sources, i.e., a red laser light source 30-1, a green laser light source 30-2, and a blue laser light source 30-3, and a near-infrared laser light source 35 can be used as the light source in the laser module 1001.

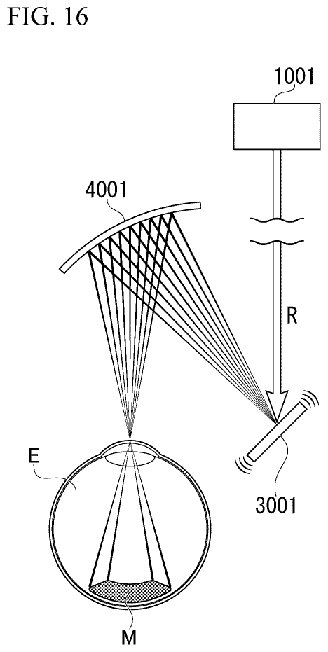

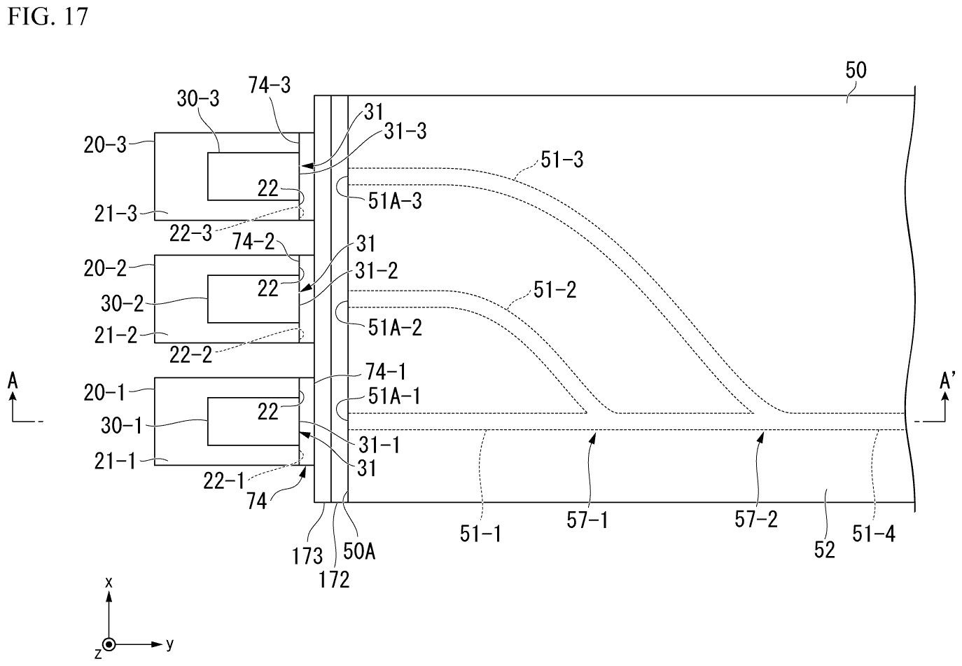

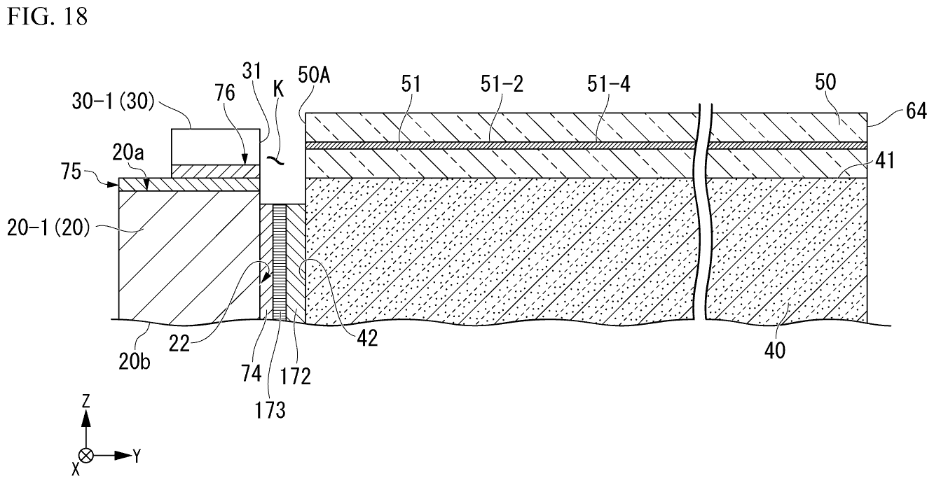

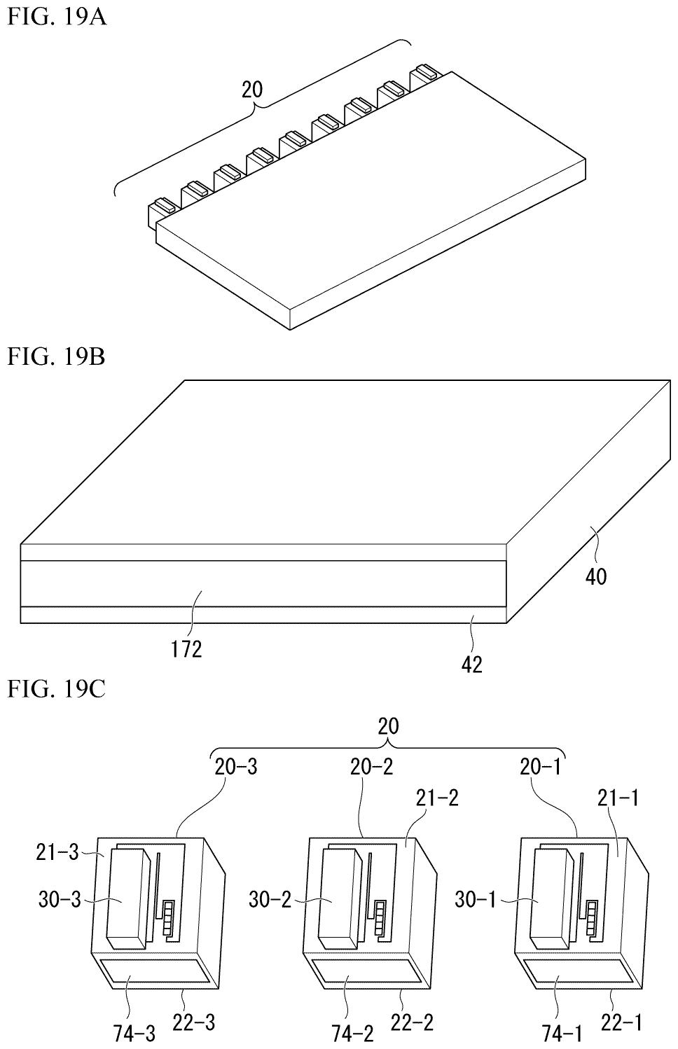

As shown in FIG. 16, laser light applied from the laser module 1001 attached to an eyeglasses frame is reflected by the optical scanning mirror 3001 and the reflected light is reflected toward a person's eyeball E by a mirror 4001 and can enter the eyeball E to project an image (a video) directly onto a retina M.

By providing an eye tracking mechanism, an image is projected directly onto the retina while eye tracking is performed. A known eye tracking mechanism can be used.

The optical scanning mirror 3001 is, for example, a MEMS mirror. In order to project a 2D image, it is preferably a biaxial MEMS mirror that vibrates to reflect laser light by changing an angle in the horizontal direction (X-direction) and the vertical direction (Y-direction).

As the optics system 2001 that optically processes the laser light output from the laser module 1001, a collimator lens 2001a, a slit 2001b, and an ND filter 2001c are provided. This optics system is an example and may have other configurations.

The optical engine 5001 includes a laser driver 1100, an optical scanning mirror driver 1200, and a video controller 1300 that controls these drivers.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the present disclosure. Accordingly, the disclosure is not to be considered as being limited by the foregoing description, and is only limited by the scope of the appended claims.

### EXPLANATION OF REFERENCES

20 Laser light source base
30 Laser light source
40 Optical waveguide substrate
50 Optical waveguide layer
100, 100A, 100B Laser assembly
110 Package
1000, 1001, 2000 Laser module
5001 Optical engine module
10000 XR glasses

What is claimed is:

1. A laser assembly comprising:
a plurality of laser light sources;
a plurality of laser light source bases having main surfaces on which the plurality of laser light sources are placed and arranged apart from each other;
an optical waveguide substrate having a main surface on which an optical waveguide layer having optical waveguides configured to guide laser light output from the plurality of laser light sources is provided; and
a plurality of metal films configured to bond the plurality of laser light source bases with the optical waveguide substrate,
wherein the plurality of metal films correspond to the plurality of laser light source bases and are arranged apart from each other.

2. The laser assembly according to claim 1, wherein each of the plurality of metal films is arranged in a recess provided on a bonding surface of the optical waveguide substrate.

3. The laser assembly according to claim 1, wherein each of the plurality of metal films is arranged on a substrate-side bonding part defined by a groove part formed on the bonding surface of the optical waveguide substrate.

4. The laser assembly according to claim 1, wherein the metal film includes Sn and a metal that can be eutectic with Sn.

5. The laser assembly according to claim 1, wherein an antireflection film is formed between the bonding surface of the optical waveguide substrate and the metal film.

6. The laser assembly according to claim 1, wherein the optical waveguide layer is a planar lightwave circuit (PLC) made of a glass material.

7. The laser assembly according to claim 1, wherein the optical waveguide layer is a PLC made of a lithium niobate film.

8. A laser module having a package in which the laser assembly according to claim 1 is housed.

9. XR glasses comprising the laser module according to claim 8.

10. A laser module having a package in which the laser assembly according to claim 2 is housed.

11. A laser module having a package in which the laser assembly according to claim 3 is housed.

12. A laser module having a package in which the laser assembly according to claim 4 is housed.

13. A laser module having a package in which the laser assembly according to claim 5 is housed.

14. A laser module having a package in which the laser assembly according to claim 6 is housed.

15. A laser module having a package in which the laser assembly according to claim 7 is housed.

16. XR glasses comprising the laser module according to claim 10.

17. XR glasses comprising the laser module according to claim 11.

18. XR glasses comprising the laser module according to claim 12.

19. XR glasses comprising the laser module according to claim 13.

20. XR glasses comprising the laser module according to claim 14.
